(19) United States
(12) Patent Application Publication
(10) Pub. No.: US 2014/0242364 A1
(43) Pub. Date: Aug. 28, 2014

(54) POLYCARBONATE COMPOSITIONS HAVING GOOD METALLIZABILITY

(71) Applicant: BAYER INTELLECTUAL PROPERTY GMBH, Monheim (DE)

(72) Inventors: Alexander Meyer, Dusseldorf (DE); Rafael Oser, Krefeld (DE)

(21) Appl. No.: 14/348,929

(22) PCT Filed: Oct. 5, 2012
(86) PCT No.: PCT/EP2012/069740

§ 371 Date: Apr. 1, 2014

(30) Foreign Application Priority Data
Oct. 7, 2011 (EP) 11184317.3

(51) Int. Cl. C08L 69/00; C23C 16/44; C08L 83/04

(52) U.S. Cl. CPC C08L 69/00; C08L 83/04; C23C 16/44
USPC 428/216; 525/462; 524/537; 428/412; 428/336; 427/488; 427/569; 427/579; 427/489

(57) ABSTRACT

The invention relates to blends of special copolycarbonates and special polyetherimides or special polyarylsulfones which have good metallizability and to compositions of said copolycarbonate blends optionally containing additives which are selected from the group of thermo stabilizers and release agents, to the use thereof for producing molded parts and to molded parts produced therefrom. The invention further relates to multilayer products comprising a substrate which contains the compositions according to the invention, said products comprising at least one further layer, preferably a metal layer, on at least one side, and to methods for producing said products.

The invention relates to blends of specific copolycarbonates and of specific polyetherimides or of specific polyaryl sulfones with good metalizability, and to compositions made of said copolycarbonate blends optionally with additives selected from the group of the heat stabilizers and mold-release agents, to use of these for the production of molded parts, and to molded parts obtainable therefrom. The invention further relates to multilayer products comprising a substrate comprising the compositions of the invention which on one side have at least one further layer, preferably one metal layer, and also to processes for the production of these products.

Because polycarbonates have high heat resistance they are used inter alia in fields in which a relatively high level of thermal stress is likely to occur. By using specific copolycarbonates (an example being a copolycarbonate based on bisphenol A and bisphenol TMC (1,1-bis(4-hydroxyphenyl)-3,3,5-trimethylcyclohexane) a further increase in heat resistance can be obtained. The polycarbonates are therefore also suitable for the production of lenses, reflectors, lamp covers and lamp housings, etc., which have exposure to a relatively high level of thermal stress. These applications practically always demand a relatively high level of thermal properties, such as high Vicat softening point (heat resistance) or high glass transition temperature in combination with adequate mechanical properties.

Polycarbonates made of bisphenol A and bisphenol TMC are obtainable commercially with trademark Apec® from Bayer Materialscience AG.

Copolycarbonates based on cycloalkylidenediphenols are known and have been described various publications.

DE 3 903 103 A1, EP 414 083 A2, and EP 359 953 A1 describe the production and use of polycarbonates based on cycloalkylidenediphenols.

A number of compositions comprising copolycarbonates with cycloalkylidenediphenols and various other polymeric components have also been described.

EP 362 646 A2 describes blends of copolycarbonates with cycloalkylidenediphenols and with rubbers.

EP 401 629 A2 describes blends with high temperature resistance made of copolycarbonates comprising cycloalkylidenebisphenols and ABS polymers.

EP 410 239 A1 describes mixtures of copolycarbonates comprising cycloalkylidenediphenols and polyester.

DE 3 933 544 A1 describes blends of cycloalkylidenediphenol-based polycarbonates, and of polyamides and elastomers.

None of said applications describes improved optical properties in metalized moldings at temperatures above 160° C. No publication describes blends of cycloalkylidenediphenol-based copolycarbonates and of polyetherimides or of specific polyaryl ether sulfone or polyaryl sulfone. The available prior art does not reveal how the problem described above can be solved.

U.S. Pat. No. 6,883,938 B1 describes reflectors or metalized moldings made of substrate materials which comprise norbornene derivatives. Said reflectors are not based on cycloalkylidenediphenol-derived polycarbonates. Said patent provides no information relevant to the achievement of the object.

U.S. Pat. No. 7,128,959 B2 describes metalized moldings. Polycarbonates, polysulfones, or polyetherimides, or a mixture of these can be used as substrate material in that document. In order to ensure good metalization, a base layer must be applied to the respective substrate before metalization. The problem described here cannot be solved by the application of a base layer. In the case of the composition described in the present invention, the application of a base layer is not necessary.

These materials must not only have good processability and good mechanical properties but also comply with further requirements, for example good surface quality in the resulting injection-molded part/extrudate, and good metal adhesion.

Heat resistance and mechanical properties can be varied widely, depending on bisphenols used and on suitable adjustment of the molecular weight of the homo- and copolycarbonates. However, the requirement for a further improvement in metal adhesion for certain applications continues. Specifically in the field of reflectors, good metal adhesion is essential.

As described above, the corresponding metalized parts must have high heat resistance. No deterioration is permitted either in mechanical properties or in optical properties, e.g. the quality of the metal surface. However, it has been found that at very high temperatures the optical quality of metalized moldings made of specific copolycarbonates which have Vicat softening points above 160° C., in particular above 170° C., and which comprise inter alia 1,1-bis(4-hydroxyphenyl)-cyclohexane derivatives is often not adequate for specific applications. At high temperatures (in particular at temperatures or temperature peaks above 170° C.), moldings of this type which have been metalized and pretreated under specific conditions, in particular under plasma conditions, have a tendency toward blistering (blistering and cracking of the coating). This can lead to failure of the corresponding molding in the respective application. The blistering causes the metal surface to lose its uniform appearance—and the reflection of light is moreover adversely affected.

Surprisingly, this phenomenon occurs in particular to an increased extent when the abovementioned copolycarbonates comprise certain additives, such as titanium dioxide. However, titanium dioxide is used to establish a certain color in resultant moldings, and is therefore an important constituent of the compositions. Omission of titanium dioxide leads to use of other pigments and compounds which are markedly more expensive and which therefore render the process less economic, and/or are unstable on aging. Other colorants or pigments, such as carbon black, can be used alongside titanium dioxide. An example of a color frequently desired in the field of electronics is gray (for example what is known as “electric gray”).

It was therefore an object to provide white- or gray-colored polycarbonate compositions which have Vicat softening points above 160° C., preferably above 170° C., and which comprise copolycarbonates based on 1,1-bis(4-hydroxyphenyl)cyclohexane derivatives, and which can be metalized easily, and which moreover lead to defect-free metal surfaces on the correspondingly metalized molding.

Another object consisted in providing white- or gray-colored products. The intention here is that these products have superior metalizability.

Another object was to develop a multilayer structure composed of a substrate material comprising at least 60% by weight, based on the total amount of the bisphenol derivatives, of copolycarbonate based on 1,1-bis(4-hydroxyphenyl)cyclohexane derivatives, and of at least one metal layer, where these have excellent surface quality and also retain the surface quality at high temperatures.

Surprisingly, the object was achieved through certain polycarbonate mixtures which comprise specific polyetherimides and/or specific polyaryl sulfones. Metallized moldings made of said compositions obtain a defect-free metal surface even at very high service temperatures of from 160 to 210° C.

The invention achieves the object through a polymer composition comprising
A) (hereinafter also termed component A) from 60% by weight to 99% by weight, preferably from 65% by weight to 98% by weight, and with particular preference from 70% by weight to 95% by weight (based on the sum of the parts by weight of components A+B) of one or more copolycarbonates with a Vicat softening points (measured according to DIN ISO 306) above 160° C., preferably above 165° C., with particular preference above 170° C. comprising as chain terminator (terminal group) a structural unit of the formula (1)

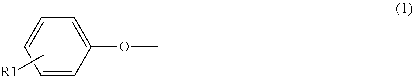

in which
R1 are hydrogen or C₁-C₁₈-alkyl; very particular preference is given to the following as chain terminator: phenol or tert-butylphenol or n-butylphenol, in particular phenol and p-tert butylphenol,
and
   comprises at least one diphenol unit of the formula (2),

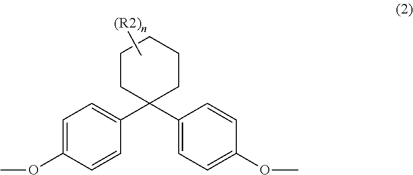

in which
R2 are C₁-C₄-alkyl, preferably methyl, ethyl, propyl, isopropyl, and butyl and isobutyl moieties, particularly preferably methyl,
and n is 0, 1, 2, or 3, preferably 2 or 3.
B) (hereinafter also termed component B) from 1% by weight to 40% by weight, preferably from 2% by weight to 35% by weight, and with particular preference from 5% by weight to 30% by weight (based on the sum of the parts by weight of components A+B) of one or more specific polyaryl sulfones and/or specific polyetherimides which have the general formula (I), (II), or (III) as repeating unit:

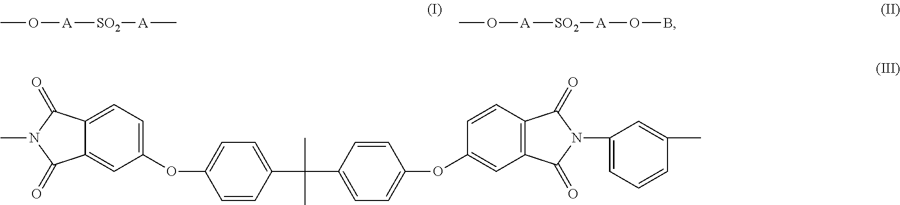

in which A and B can be optionally substituted aromatic moieties. The aromatic moieties are composed of from 6 to 40 C atoms, preferably of from 6 to 21 C atoms, which comprise one or more optionally condensed aromatic nuclei, where the nuclei can optionally comprise heteroatoms. These aromatic nuclei can optionally have substitution by linear or branched or cycloaliphatic C₁- to C₁₅-moieties or by halogen atoms. The aromatic nuclei can have bonding by way of carbon bonds or by way of heteroatoms as bridging member.
C) optionally from 0.0% by weight to 1.0% by weight, preferably from 0.01% by weight to 0.50% by weight, particularly preferably from 0.01% by weight to 0.40% by weight (based on the sum of the parts by weight of components A+B=100) of one or more mold-release agents (hereinafter also termed component C).
D) optionally from 0.00% by weight to 0.20% by weight, preferably from 0.01% by weight to 0.10% by weight (based on the sum of the parts by weight of components A+B=100), of one or more heat stabilizers or processing stabilizers, preferably selected from the group of the phosphines, phosphites, and phenolic antioxidants, and mixtures of these (hereinafter also termed component D).
E) optionally from 0.00% by weight to 0.05% by weight, preferably from 0.01% by weight to 0.04% by weight (based on the sum of the parts by weight of components A+B=100) of one or more colorants (hereinafter also termed component E).
F) optionally from 0.0% by weight to 5% by weight, preferably from 0.01% by weight to 1.00% by weight (based on the sum of the parts by weight of components A+B=100) of one or more additives (hereinafter also termed component F).

### Component A

Preferred diphenol units of the formula (2) derive by way of example from 1,1-bis(4-hydroxyphenyl)cyclohexane and 1,1-bis(4-hydroxyphenyl)-3,3,5-trimethylcyclohexane, preferably 1,1-bis(4-hydroxyphenyl)-3,3,5-trimethylcyclohexane.

Preference is given here to copolycarbonates which comprise from 20% by weight to 98% by weight, with particular preference from 25% by weight to 95% by weight, of diphenol unit of the formula (2).

Suitable dihydroxyaryl compounds other than the diphenols of the formula (2) for the production of the copolycarbonates are those of the formula (3)

HO—Z—OH (3)

in which
Z is an aromatic moiety which has from 6 to 30 C atoms and which can comprise one or more aromatic nuclei and can have substitution and can comprise aliphatic or cycloaliphatic moieties and, respectively, alkylaryl moieties or heteroatoms as bridging members.

It is preferable that Z in formula (3) is a moiety of the formula (3a)

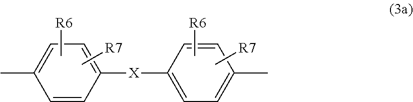

in which
R6 and R7 are mutually independently H, C₁-C₁₈-alkyl-, C₁-C₁₈-alkoxy, halogens such as Cl or Br, or respectively optionally substituted aryl- or aralkyl, preferably H or C₁-C₁₂-alkyl, particularly preferably H or C₁-C₈-alkyl, and very particularly preferably H or methyl, and
X is —CO—, —O—, —S—, C₁- to C₆-alkylene, C₂- to C₅-alkylidene, or C₆- to C₁₂-arylene, which can optionally have been condensed with further aromatic rings comprising heteroatoms.

It is preferable that X is, C₁ to C₅-alkylene, C₂ to C₅-alkylidene, —O—, —SO—, —CO—, —S—, —SO₂—, isopropylidene, or oxygen, in particular isopropylidene.

Examples of suitable diphenols of the formula (3) for the production of the copolycarbonates to be used in the invention are hydroquinone, resorcinol, bis(hydroxyphenyl)alkanes, bis(hydroxyphenyl) sulfides, bis(hydroxyphenyl)ethers, bis(hydroxyphenyl) ketones, bis(hydroxyphenyl) sulfones, bis(hydroxyphenyl) sulfoxides, [alpha],[alpha]-bis(hydroxyphenyl)diisopropylbenzenes, and also ring-alkylated and other alkylated and ring-halogenated compounds related to these.

Preference is further given to the following diphenols of the formula (3): 4,4′-dihydroxybiphenyl, 2,2-bis(4-hydroxyphenyl)-1-phenylpropane, 1,1-bis(4-hydroxyphenyl)phenylethane, 2,2-bis(4-hydroxyphenyl)propane, 2,2-bis(3-methyl-4-hydroxyphenyl)propane, 2,4-bis(4-hydroxyphenyl)-2-methylbutane, 1,3-bis[2-(4-hydroxyphenyl)-2-propyl]benzene (bisphenol M), 2,2-bis(3-methyl-4-hydroxyphenyl)propane, bis(3,5-dimethyl-4-hydroxyphenyl)methane, 2,2-bis(3,5-dimethyl-4-hydroxyphenyl)propane, bis(3,5-dimethyl-4-hydroxyphenyl) sulfone, 2,4-bis(3,5-dimethyl-4-hydroxyphenyl)-2-methylbutane, 1,3-bis[2-(3,5-dimethyl-4-hydroxyphenyl)-2-propyl]benzene.

Particularly preferred diphenols of the formula (3) are 2,2-bis(4-hydroxyphenyl)propane (BPA), and 2,2-bis(3-methyl-4-hydroxyphenyl)propane.

Particular preference is given to copolycarbonates made of bisphenol A and bisphenol TMC.

These and other suitable bisphenols are obtainable commercially and are described by way of example in “H. Schnell, Chemistry and Physics of Polycarbonates, Interscience Publishers, New York 1964, pp. 28 ff.; pp. 102 ff.”, and in “D. G. Legrand, J. T. Bendier, Handbook of Polycarbonate Science and Technology, Marcel Dekker New York 2000, pp. 72 ff.”.

The thermoplastic copolycarbonates have molar masses Mw (weight average Mw, ascertained via gel permeation chromatography GPC) of from 12 000 to 120 000 g/mol, preferably of from 15 000 to 80 000 g/mol, in particular of from 18 000 to 60 000 g/mol, very particularly preferably of from 18 000 to 40 000 g/mol. Molar masses can also be reported via the number averages Mn, which are likewise determined by means of GPC after prior calibration to polycarbonate.

### Component B

A can by way of example be phenylene, alkylphenylene, alkoxyphenylene, or corresponding chlorine- or fluorine-substituted derivatives, preferably unsubstituted phenylene moieties.

B is preferably moieties which derive from bisphenols and which are based on the general formula (IV) or (V)

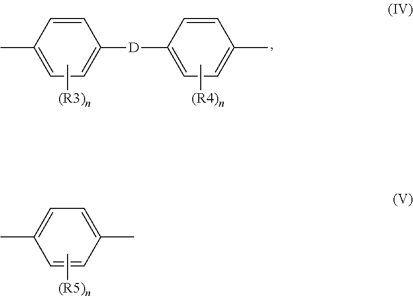

where R3, R4, and R5 respectively mutually independently, being identical or different, is hydrogen, halogen, C₁-C₆-alkyl, or C₁-C₆-alkoxy-, preferably hydrogen, fluorine, chlorine, or bromine,
n is an integer from 1 to 4, preferably 1, 2, or 3, in particular 1 or 2,
D is a chemical bond —CO—, —O—, or —S—, preferably a single bond.

Preference is given here to polymers of the formula (I) where A is a phenylene moiety. These materials, known as polyether sulfones (CAS: 25608-63-3) are by way of example obtainable with trademark Ultrason® E 2010 from BASF SE (67056 Ludwigshafen, Germany).

Preference is further given to polymers of the formula (II) where A is a phenylene moiety and B is a phenylene moiety.

Preference is in particular given to polymers of the formula (II) where A is a phenylene moiety and B is a biphenylene moiety. These materials, known as polyphenyl sulfones (CAS 25608-64-4) are obtainable with trademark Radel® R (e.g. Radel® R 5900) from Solvay Advanced Polymers or Ultrason® P from BASF SE (67056 Ludwigshafen, Germany).

Preference is further given to polymers of the formula (III). These polymers are obtainable by way of example with trademark Ultem® (CAS 61128-46-9) (Sabic Innovative Plastics).

Mixtures of the abovementioned polymers are also possible.

The polymer composition can comprise additives.

Preferred suitable mold-release agents (component C) are pentaerythritol tetrastearate, glycerol monostearate, stearyl stearate and propoanediol mono- and distearate. They are used alone or in a mixture.

A preferred suitable heat stabilizer (component D) is tris(2,4-di-tert-butylphenyl) phosphite (Irgafos 168), tetrakis(2,4-di-tert-butylphenyl) [1,1 biphenyl]-4,4′-diylbisphosphonite, trisoctyl phosphate, octadecyl 3-(3,5-di-tert butyl-4-hydroxyphenyl)propionate (Irganox 1076), bis(2,4-dicumylphenyl)pentaerythritoldiphosphite (Doverphos S-9228), bis(2,6-di-tert-butyl-4-methyl-phenyl)pentaerythritoldiphosphite (ADK STAB PEP-36), or triphenylphosphine. They are used alone or in a mixture (e.g. Irganox B900 or Doverphos S-92228 with Irganox B900 or, respectively, Irganox 1076).

Colorants (component E) can moreover be added, examples being organic dyes or pigments or inorganic pigments, individually, in a mixture, or else in combination with stabilizers; or organic or inorganic scattering pigments can be added. It is preferable here that the composition of the invention is free from titanium dioxide.

Suitable UV stabilizers (component F) are preferably 2-(2′-hydroxyphenyl)benzotriazoles, 2-hydroxybenzophenones, esters of substituted and unsubstituted benzoic acids, acrylates, sterically hindered amines, oxamides, 2-(2-hydroxyphenyl)-1,3,5-triazines, particular preference being given to substituted benzotriazoles such as Tinuvin 360, Tinuvin 350, Tinuvin 234, Tinuvin 329, or UV CGX 006 (Ciba).

The composition can moreover comprise other commercially available polymer additives (component F) such as flame retardants, flame retardant synergists, antidripping agents (for example compounds of the substance classes of the fluorinated polyolefins, of the silicones, or else aramid fibers), nucleating agents, antistatic agents (for example carbon fibers, carbon nanotubes, conductive carbon blacks, or else organic antistatic agents such as polyalkylene ethers, alkylsulfonates, or polyamide-containing polymers) in amounts that do not impair the mechanical properties of the composition to the extent that the target property profile is no longer achieved.

Suitable additives are described by way of example in “Additives for Plastics Handbook”, John Murphy, Elsevier, Oxford 1999, or in “Plastics Additives Handbook”, Hans Zweifel, Hanser, Munich 2001, or in WO 99/55772, pp. 15-25.

The present application further provides multilayer systems composed of a layer i) composed of a substrate material made of a mixture of component A) and B), and also optionally one or more of components C) to E),

and also of at least one layer ii) formed from at least one metal and/or at least one metal compound, where the metal is preferably composed of aluminum, silver, chromium, titanium, or palladium, preferably of aluminum. Alloys comprising said metals are also possible. Metal oxides and -nitrides are moreover also included, an example being CrOₓ or TiNₓ.

The thickness of i) here is preferably from 0.05 mm to 6.00 mm, particularly preferably from 0.1 mm to 5.0 mm, and with particular preference from 0.5 mm to 4.0 mm.

The thickness of the layer ii) is preferably from 10 nm to 1000 nm, with particular preference from 30 nm to 500 nm, and very particularly preferably from 40 nm to 300 nm.

In one preferred embodiment, the layer ii) bears a protective layer iii) comprising plasma-polymerized siloxanes of thickness from 5 nm to 200 nm, preferably from 15 nm to 150 nm, very particularly preferably from 20 nm to 100 nm.

In another preferred embodiment, there can moreover be a layer iv) present which prevents condensation forming on the surface. The thickness of this layer is from 1 to 50 nm. The starting materials for the production of this layer, and also the application process, are stated in EP 857 518 A.

An entirely surprising fact was that other—structurally similar—compositions lead to very poor surface properties: thus, by way of example, it has been shown for the purposes of the invention that multilayer structures made of polymers of component A) with conventional polysulfones (CAS: 25135-51-7) comprising a metal layer have a tendency toward blistering at high temperatures. In view of the very similar polymer structures, this was highly surprising and not foreseeable.

The injection moldings or extrudates produced from the copolycarbonates and copolycarbonate compositions of the invention exhibit significantly improved thermal properties (glass transition temperature, and also Vicat point) in conjunction with good metalizability. Surface quality is retained even on exposure to a high level of thermal stress. Mechanical, thermal, and rheological properties remain almost unaltered here when comparison is made with the standard copolycarbonates (e.g. Apec).

The thermoplastic molding compositions of the invention are produced by mixing the respective constituents in a known manner and compounding in the melt at temperatures of from 200° C. to 380° C., preferably from 240 to 350° C., in conventional assemblies, such as internal mixers, extruders, and twin-screw systems, and extrusion in the melt.

The polymer compositions are in particular used for the production of components where optical, thermal, and mechanical properties are utilized, examples being housings, articles in the electrical and electronics sector, for example plugs, switches, boards, lamp holders, lamp covers, lamp holders and lamp covers, reflectors, and other applications.

The extrudates and moldings made of the polymers of the invention are likewise provided by the present application.

The copolycarbonates of component A) are produced by a continuous interfacial process. The production process for the copolycarbonates to be used in the invention proceed in principle in a known manner starting from diphenols, carbonic acid derivatives, and optionally branching agents.

In general terms, the process for the synthesis of polycarbonates is known and described in numerous publications. EP 517 044 A, WO 2006/072344, and also EP 1 609 818 A, and documents cited therein describe by way of example the interfacial and the melt process for the production of polycarbonate.

The continuous process for the production of aromatic copolycarbonates uses what is known as the interfacial process. In this process, a disodium salt of a mixture of various bisphenols is used as initial charge and is phosgenated in aqueous alkaline solution (or suspension) in the presence of an inert organic solvent or preferably of a solvent mixture, which forms a second phase. With the aid of suitable catalysts, the resulting oligocarbonates, primarily present in the organic phase, are condensed to give copolycarbonates with the desired molecular weight, dissolved in the organic phase. Finally, the organic phase is isolated, and the copolycarbonate is isolated therefrom via various work-up steps, preferably via vented extruders.

The bisphenols used, and also all of the other chemicals and auxiliaries added to the synthesis, can have contamination by contaminants deriving from the synthesis, handling, and storage of same. However, it is desirable to operate with raw materials of maximum purity.

The synthesis of copolycarbonates from bisphenols and phosgene in an alkaline medium is an exothermic reaction, and is carried out in a temperature range from −5° C. to 100° C., preferably from 15° C. to 80° C., very particularly preferably from 25° C. to 65° C., and for some solvents or solvent mixtures it may be necessary to operate this process under superatmospheric pressure.

Synthesis of the copolycarbonates is carried out continuously. The reaction can therefore take place in pumped-circulation reactors, tubular reactors, or stirred-tank cascades, or a combination of these, and it is necessary here to use the abovementioned mixing units to ensure that, as far as possible, demixing of aqueous phase and organic phase does not occur until the synthesis mixture has reacted to completion, i.e. no longer comprises any hydrolyzable chlorine from phosgene or from chlorocarbonic esters.

The monofunctional chain terminators of the formula 1 or, respectively, mixtures of these that are necessary for molecular-weight regulation are introduced per se or in the form of their chlorocarbonic esters, either being introduced with the bisphenolate(s) to the reaction or else being added at any desired juncture of the synthesis, as long as the reaction mixture still comprises phosgene or chlorocarbonic acid terminal groups or, in the case of the acyl chlorides and chlorocarbonic esters as chain terminators, as long as there is a sufficient number available of phenolic terminal groups of the polymer that is being formed. However, it is preferable that the chain terminator(s) are added at a location or at a juncture after phosgenation when no residual phosgene is present any longer, but the catalyst has not yet been added, or that they are added before the catalyst, together with the catalyst, or in parallel therewith.

The amount of chain terminator to be used is from 0.5 mol % to 10 mol %, preferably from 1 mol % to 8 mol %, particularly preferably from 2 mol % to 6 mol %, based on moles of diphenols respectively used. The chain terminators can be added before, during, or after phosgenation, preferably in the form of solution in a solvent mixture made of methylene chloride and chlorobenzene (from 8 to 15% by weight).

The catalysts used in the interfacial synthesis are tertiary amines, in particular triethylamine, tributylamine, trioctylamine, N-ethylpiperidine, N-methylpiperidine, N-iso/n-propylpiperidine, particularly preferably triethylamine and N-ethylpiperidine. The catalysts can be added individually, in a mixture, or else alongside one another and in succession to the synthesis, optionally also before phosgenation, but preference is given to additions after phosgene introduction. The catalyst(s) can be added in bulk, in an inert solvent, preferably that for the polycarbonate synthesis, or else in the form of aqueous solution, and in the case of the tert-amines then in the form of ammonium salts of these with acids, preferably mineral acids, in particular hydrochloric acid. If a plurality of catalysts are used or if subquantities of the total amount of catalyst are added, it is naturally also possible to use different modes of addition at different locations or at different times. The total amount of the catalysts used is in the range from 0.001 to 10 mol %, based on moles of bisphenols used, preferably from 0.01 to 8 mol %, particularly preferably from 0.05 to 5 mol %.

The organic phase comprising the polymer must now be purified to remove all alkaline, ionic, or catalytic contaminants. Even after one or more settling procedures, optionally assisted via passes through settling tanks, stirred tanks, coalescers, or separators, or combinations of these measures—optionally with addition of water in one or more separation steps, sometimes with use of active or passive mixing units—the organic phase still comprises fractions of the aqueous alkaline phase in fine droplets, and also comprises the catalyst, generally a tertiary amine.

After most of the alkaline, aqueous phase has been removed, the organic phase is washed one or more times with dilute acids, dilute mineral acids, dilute carboxylic acids, dilute hydroxycarboxylic acids, and/or dilute sulfonic acids. Preference is given to aqueous mineral acids, in particular hydrochloric acid, phosphorous acid, and phosphoric acid, or a mixture of said acids.

Between these washing steps, or else after washing, it is optionally possible to add acids, preferably dissolved in the solvent on which the polymer solution is based. It is preferable here to use hydrogen chloride gas and phosphoric acid or phosphorous acid, and these can optionally also be used in the form of mixtures.

The multilayer structures of the invention comprise at least one substrate material comprising component A) and component B), and also a metal layer.

The application of metals to the polymer can be achieved by way of various methods, for example by vapor deposition or by sputtering. The processes are described in more detail by way of example in “Vakuumbeschichtung Bd.1 bis 5 [Vacuum coating, Vols. 1 to 5]”, H. Frey, VDI-Verlag Dusseldorf 1995 or “Oberflächen- and Dünnschicht-Technologie [Technology of surfaces and thin layers]” Part 1, R. A. Haefer, Springer Verlag 1987.

It is preferable that the metal is applied by means of DC magnetron sputtering. In order to achieve better metal adhesion and in order to clean the substrate surface, the substrates are normally subjected to plasma pretreatment. Plasma pretreatment can sometimes alter the surface properties of polymers. These methods are by way of example described by Friedrich et al. in Metallized plastics 5 & 6: Fundamental and applied aspects and H. Grünwald et al. in Surface and Coatings Technology 111 (1999) 287-296.

In one particular embodiment, there is also a protective layer applied on the metal layer of the multilayer structure, for example for protection from corrosion. The corrosion-reducing protective layer can be applied in a PECVD (plasma enhanced chemical vapor deposition) or plasma-polymerization process. Here, low-boiling-point precursors mainly based on siloxane are vaporized into a plasma and thus activated in such a way that they can form a film. Typical substances here are hexamethyldisiloxane (HMDSO), tetramethyldisiloxane, decamethylcyclopentasiloxane, octamethylcyclotetrasiloxane, and trimethoximethylsilane. Particular preference is given to HMDSO.

### EXAMPLES

The invention is described in more detail hereinafter by taking working examples, where the determination methods described here are used for all of the corresponding variables in the present invention, unless otherwise stated.

Melt volume rate (MVR) is determined according to ISO 1133 under the conditions stated below.

### Measurement of Heat Resistance by Way of Vicat Softening Point:

Vicat softening point according to DIN EN ISO 306 is measured with a needle (with circular area of 1 mm²) A test force of 50 N (test force B) is applied thereto. The abovementioned test specimen is exposed to a defined heating rate of 120 K/h. The Vicat point has been reached when the penetration depth achieved by the penetrator is 1 mm. It is measured according to DIN ISO 306.

### Materials:

### Copolycarbonate Component A):

Type 1: Copolycarbonate comprising 85% by weight of 1,1-bis(4-hydroxyphenyl)-3,3,5-trimethylcyclohexane and 15% by weight of bisphenol A with phenol as chain terminator and with an MVR of 5 cm³/(10 min) (330° C.; 2.16 kg) in accordance with ISO 1133 and with a Vicat softening point of 218° C. (ISO 306; 50 N; 120 K/h).

Type 2: Copolycarbonate comprising 85% by weight of 1,1-bis(4-hydroxyphenyl)-3,3,5-trimethylcyclohexane and 15% by weight of bisphenol A with phenol as chain terminator and with an MVR of 5 cm³/(10 min) (330° C.; 2.16 kg) in accordance with ISO 1133 is compounded with 0.004% by weight of carbon black (Lampblack 101, Evonik Carbon Black GmbH, 60287 Frankfurt a. M., Germany, Color Index: 77262) and 0.1% by weight of titanium dioxide (Kronos 2230; Kronos International Inc., 51373 Leverklusen, Germany) under conditions described above. The Vicat softening point of the resultant material is 213° C. (ISO 306; 50 N; 120 K/h).

### Component B)

Polyphenylene sulfone of the formula (II): Radel R5900NT (CAS 25608-64-4) from Solvay Advanced Polymers GmbH (Dusseldorf, Germany) with an MVR of 16.3 cm³/(10 min) (360° C.; 10 kg) in accordance with ISO 1133.

Polysulfone not covered by formula (I) or (II) for comparative example: Ultrason S 6010 (CAS: 25154-01-2) with an MVR of 30 cm³/(10 min) (360° C.; 10 kg) in accordance with ISO 1133.

### Compounding

The materials were compounded in a twin-screw extruder from KraussMaffei Berstorff, TYP ZE25, at a barrel temperature of 320° C. or a melt temperature of about 340° C. and with a rotation rate of 110 rpm with the component quantities stated in the examples.

### Production of the Test Specimens:

Metalization properties were studied by preparing optical-quality rectangular injection-molded plaques measuring 150×105×3.2 mm with side gating. Melt temperature was from 300 to 330° C., and mold temperature was 100° C. The respective pellets were dried at 120° C. in a vacuum drying oven for 5 hours before processing.

### Metalization Process:

All of the plaques were stored for 21 days at 50% humidity and 23° C. prior to the coating process.

The coating system was composed of a vacuum chamber where the specimens were positioned on a rotating specimen holder. The specimen holder rotated at about 20 rpm. Ionized air was blown onto the test specimen to free them from dust before they were introduced into the vacuum chamber. The vacuum chamber with the test specimens was then evacuated to a pressure p≦1·10⁻⁵ mbar. Argon gas was then admitted until a pressure of 0.1 mbar was reached, and a plasma was ignited for 2 min with a power level of 1000 W, and the specimens were exposed to this plasma (plasma pretreatment). Plasma source used comprised a diode arrangement composed of 2 parallel metal electrodes, and was operated with an alternating frequency of 50 kHz and with a voltage above 1000 V. The specimens were then metalized. For this, Ar gas was permitted to enter the system with a pressure of 5·10⁻³ mbar. An aluminum layer of thickness about 100 nm was applied to the specimens by means of DC magnetron with a power density of 6.4 W/cm². The sputtering time was 2.5 min A corrosion-protection layer made of HMDSO was then applied by means of plasma polymerization. For this, HMDSO was vaporized, and the vapor was permitted to enter the vacuum chamber until the resultant pressure was about 0.07 mbar. A plasma was then ignited, using the diode arrangement described above at 1000 W, while the corrosion-protection layer was applied for 1 minute.

Test for Surface Quality after Heat-Aging:

The test is carried out directly after the metalizing process. This means that the plaques were subjected to this test within one hour after metalization.

In this test, the metalized plaques are aged in a chamber under controlled conditions for 2 to 3 hours at 45° C. and 100% relative humidity. Directly after this conditioned aging, the plaques are aged for one hour at 195° C. in an oven.

The metal surface is then assessed.

### Visual Assessment:

The surface is studied for raised blister-type areas, clouding of the metal layer, and iridescence. Plaques exhibiting neither iridescence nor clouding nor blisters, are characterized as “very good”.

### Example 1 (Comparative Example)

Copolycarbonate of component A) type 1 is processed as described above to give moldings. The metalization is achieved as described above.

Table 1 lists the result of heat-aging.

### Example 2 (of the Invention)

Copolycarbonate of component A) type 1 is compounded with 10% by weight of component B) Radel R5900NT under the conditions described above. The test specimens described above are produced and metalized.

Table 1 lists the result of heat-aging.

### Example 3 (of the Invention)

Copolycarbonate of component A) type 1 is compounded with 15% by weight of component B) Radel R5900NT under the conditions described above. The test specimens described above are produced and metalized.

Table 1 lists the result of heat-aging.

### Example 4 (Comparative Example)

Copolycarbonate of component A) type 1 is compounded with 10% by weight of component B) Ultrason S 6010 under the conditions described above. The test specimens described above are produced and metalized.

Table 1 lists the result of heat-aging.

### Example 5 (Comparative Example)

Copolycarbonate of component A) type 2 is processed as described above to give moldings, and metalized.

Table 1 lists the result of heat-aging.

TABLE 1

| | | | Visual assessment |
|---|---|---|---|
| | | Color of | of surface quality |
| | Vicat | unmetalized | (metalized structure |
| Example No. | [° C.] | plaque | after heat-aging) |
| 1 (comparison) | 218 | transparent | blisters in some places; |
| | | | metal separation |
| 2 (of the invention) | 218 | gray, | very good |
| | | nontransparent | |
| 3 (of the invention) | 218 | gray, | very good |
| | | nontransparent | |
| 4 (comparison) | 218 | gray, | blisters in some places; |
| | | nontransparent | metal separation |
| 5 (comparison) | 213 | gray, | blisters over entire area; |
| | | nontransparent | metal separation |

A copolycarbonate of Example 1 is seen to have a tendency toward surface defects such as metal separation under the prevailing test conditions. Nor does the copolycarbonate of Example 1 comply with the optical requirements (gray and nontransparent). Although the material of Example 5 complies with the color requirements, it exhibits serious surface defects under the selected test conditions. In contrast, Examples 2 and 3 of the invention comply with the optical requirements and exhibit the desired surface resistance to thermal stress. It was surprising that, as shown in Example 5, formulations similar to the compositions of the invention, i.e. with similar polymer compositions in the base layer, do not lead to the desired result.

1. A composition comprising
A) from 60% by weight to 99% by weight based on the sum of parts by weight of components A+B, of at least one copolycarbonate with a Vicat softening point of at least 160° C. comprising as chain terminator, terminal group, a structural unit of formula (1) 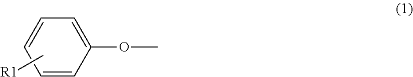
in which
R1 comprises hydrogen or C₁-C₁₈-alkyl
and
comprises at least one diphenol unit of formula (2), 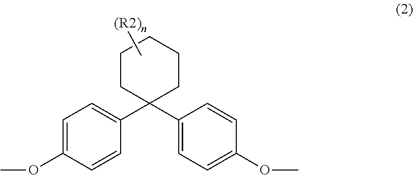
in which
R2C₁-C₄-alkyl,
n 0, 1, 2, or 3,
and
B) from 1% by weight to 40% by weight based on the sum of parts by weight of components A+B, of at least one specific polyaryl sulfone and/or specific polyetherimide which have formula (I), (II), or (III) as repeating unit: 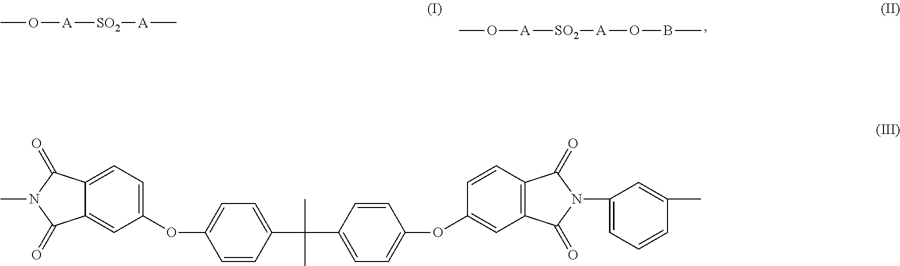
in which A and B can be optionally substituted aromatic moieties, where the aromatic moieties comprising from 6 to 40 C atoms which comprise at least one optionally condensed aromatic nuclei, where the nuclei can optionally comprise at least one heteroatom,
a such that the sum of the parts by weight of components A+B in the composition are 100.

2. The composition as claimed in claim 1, comprising a highly heat-resistant polycarbonate according to component A), in which phenol or tert-butylphenol or n-butylphenol is used as chain terminator.

3. The composition as claimed in claim 1, comprising a highly heat-resistant polycarbonate according to component A), in which R2 comprises at least one of methyl, ethyl, propyl, isopropyl, and butyl and isobutyl moieties, and n is 2 or 3.

4. The composition as claimed in claim 2, wherein the highly heat-resistant polycarbonate according to component A) is a copolycarbonate made of bisphenol A and bisphenol TMC.

5. The composition as claimed in claim 1, comprising from 0 to 1% by weight based on the sum of parts by weight of components A+B=100 of one or more mold-release agents, component C.

6. The composition as claimed in claim 1, comprising from 0 to 0.2% by weight based on the sum of parts by weight of components A+B=100 of one or more heat stabilizers and/or processing stabilizers, component D.

7. The composition as claimed in claim 1, comprising from 0 to 0.05% by weight based on the sum of parts by weight of components A+B=100 of one or more colorants component E.

8. A composition as claimed in claim 1 capable of being used for producing a molding.

9. A molding comprising a composition as claimed in claim 1.

10. The molding of claim 9, comprising a highly heat-resistant polycarbonate, and having a surface coating made of a metal layer.

11. The molding as claimed in claim 10, having a surface coating made of a layer made of at least one metal and/or at least one metal compound with a thickness of from 10 to 1000 nm.

12. The molding as claimed in claim 11, having a further surface coating composed of plasma-polymerized siloxanes of thickness from 5 nm to 200 nm.

13. The molding as claimed in claim 10, having a further surface coating.

14. The molding as claimed in claim 9 wherein the molding is a part of a motor vehicle, rail vehicle, aircraft, or watercraft, or foil, profile, and/or housing part of any type.

15. A multilayer product comprising a substrate layer which at least on one side has a further layer, where the substrate layer is produced from a composition claimed in claim 1.

16. The multilayer product as claimed in claim 15, wherein the layer on the substrate layer is a metal layer.

17. The multilayer product as claimed in claim 16, wherein on the metal layer a further protective layer has been applied.

18. A process for producing a multilayer product as claimed in claim 15, wherein the protective layer is applied in a PECVD and/or plasma-polymerization process.

19. The process for producing a multilayer product as claimed in claim 18, wherein the protective layer applied by PECVD and/or plasma-polymerization process is from one or more volatile components selected from the group consisting of hexamethyldisiloxane (HMDSO), tetramethyldisiloxane, decamethylcyclopentasiloxane, octamethylcyclotetrasiloxane, and trimethoximethylsilane.
